(19) United States
(12) Patent Application Publication
(10) Pub. No.: US 2024/0185058 A1
(43) Pub. Date: Jun. 6, 2024

(54) SEMICONDUCTOR FILM THICKNESS PREDICTION USING MACHINE-LEARNING

(71) Applicant: Applied Materials, Inc., Santa Clara, CA (US)

(72) Inventors: Nojan Motamedi, Sunnyvale, CA (US); Dominic J. Benvegnu, La Honda, CA (US); Kiran L. Shrestha, San Jose, CA (US)

(73) Assignee: Applied Materials, Inc., Santa Clara, CA (US)

(21) Appl. No.: 18/075,216

(22) Filed: Dec. 5, 2022

(51) Int. Cl. G06N 3/08

(52) U.S. Cl. CPC G06N 3/08

(57) ABSTRACT

A machine-learning model may be used to estimate a film thickness from a spectral image captured from a semiconductor substrate during processing. Instead of using actual measurements from physical substrates to train the model, simulated images may be generated for a wide variety of predefined thickness profiles. Simulated training data may be rapidly generated by receiving a film thickness profile representing a film on a semiconductor substrate design. A light source may be simulated being reflected off of the film on the semiconductor substrate and being captured by a camera. The spectral data captured by the camera may be converted into one or more images for a wafer with the film thickness profile. The images may then be labeled with thicknesses from the film thickness profile for training a machine-learning model.

### TECHNICAL FIELD

This disclosure relates to using optical metrology to detect the thickness of a layer on a substrate using a machine-learning approach. More specifically, this disclosure describes techniques for generating training data for a machine-learning model.

### BACKGROUND

An integrated circuit is typically formed on a substrate by the sequential deposition of conductive, semiconductive, or insulative layers on a silicon wafer. Planarization of a substrate surface may be required for the removal of a filler layer or to improve planarity for photolithography during fabrication of the integrated circuit. Chemical mechanical polishing (CMP) is one accepted method of planarization. This planarization method typically requires that the substrate be mounted on a carrier or polishing head. The exposed surface of the substrate is typically placed against a rotating polishing pad. The carrier head provides a controllable load on the substrate to push it against the polishing pad. An abrasive polishing slurry is typically supplied to the surface of the polishing pad. Various optical metrology systems, e.g., spectrographic or ellipsometric, can be used to measure the thickness of the substrate layer pre-polishing and post-polishing, e.g., at an in-line or stand-alone metrology station.

As a parallel issue, advancements in hardware resources such as Graphical Processing Units (GPU) and Tensor Processing Units (TPU) have resulted in a vast improvement in the deep learning algorithms and their applications. One of the evolving fields of deep learning is computer vision and image recognition. Such computer vision algorithms are mostly designed for image classification or segmentation.

### SUMMARY

In some embodiments, a method of training models to characterize film thicknesses on semiconductor substrates may include receiving a film thickness profile representing a film on a semiconductor substrate design. The method may also include simulating a light source being reflected off of the film on the semiconductor substrate and being captured by a camera. The method may additionally include converting spectral data captured by the camera into one or more images for a wafer having the film thickness profile. The method may further include labeling the one or more images with the film thickness profile for training a machine-learning model.

In some embodiments, a system may include one or more processors and one or more memory devices. The one or more memory devices may include instructions that, when executed by the one or more processors, cause the one or more processors to perform operations including receiving a film thickness profile representing a film on a semiconductor substrate design. The operations may also include simulating a light source being reflected off of the film on the semiconductor substrate and being captured by a camera. The operations may additionally include converting spectral data captured by the camera into one or more images for a wafer having the film thickness profile. The operations may further include labeling the one or more images with the film thickness profile for training a machine-learning model.

In some embodiments, one or more non-transitory computer-readable media may store instructions that, when executed by one or more processors, cause the one or more processors to perform operations including receiving a film thickness profile representing a film on a semiconductor substrate design. The operations may also include simulating a light source being reflected off of the film on the semiconductor substrate and being captured by a camera. The operations may additionally include converting spectral data captured by the camera into one or more images for a wafer having the film thickness profile. The operations may further include labeling the one or more images with the film thickness profile for training a machine-learning model.

In any embodiments, any and all of the following features may be implemented in any combination and without limitation. The film thickness profile may include measurements of a thickness of the film extending from a center of the semiconductor substrate to a periphery of the semiconductor substrate. The film thickness profile may include thicknesses of the film at a plurality of different radii extending out from a center of the semiconductor substrate. The film thickness profile may be specific to a film material and one or more underlying film materials. The semiconductor substrate design may include a design file including a film material. Simulating the light source being reflected off of the film on the semiconductor substrate and being captured by the camera may include receiving a light spectra for a light source, where the light source may include a laser that will be directed to a physical semiconductor substrate during a semiconductor process, and/or calculating a reflected spectra from the film that will be captured by a physical camera using thin-film inference formulas, physical properties of the film, a film thickness at a location based on the film thickness profile, and underlying film properties. The semiconductor substrate design need not require a physical substrate to be manufactured or processed in order to simulate the light source being reflected off of the film and converting the spectral data into the image of the wafer. Converting the spectral data captured by the camera into the one or more images of a wafer having the film thickness profile may include translating the spectral data captured by the camera into RGB pixel values, and/or using a lookup table that stores RGB pixel values that correspond to received spectral wavelengths for the camera. Labeling the one or more images with the film thickness profile may include associating the image with a thickness measurement at a specific location on the semiconductor substrate design to generate a training pair for the machine learning model. Simulating the light source being reflected off of the film may include accessing a film material and physical properties of the film material, where the machine-learning model is trained specifically for the film material. A plurality of simulated images may be generated from the film thickness profile, where each of the plurality of simulated images may correspond to a thickness value in the film thickness profile. A plurality of different film thickness profiles may be simulated to generate a training data set for various film thicknesses for a specific film material. The one or images comprise monochrome images. The film thickness profile may include a simulated wafer defect, where the machine-learning model may be trained to recognize a wafer defect corresponding to the simulated wafer defect. The method/operations may also include adding simulated signal noise when simulating the light source being reflected off the film on the semiconductor substrate and being captured by the camera. Labeling the one or more images with the film thickness profile may include labeling the one or more images with ranges of film thicknesses.

### BRIEF DESCRIPTION OF THE DRAWINGS

A further understanding of the nature and advantages of various embodiments may be realized by reference to the remaining portions of the specification and the drawings, wherein like reference numerals are used throughout the several drawings to refer to similar components. In some instances, a sub-label is associated with a reference numeral to denote one of multiple similar components. When reference is made to a reference numeral without specification to an existing sub-label, it is intended to refer to all such multiple similar components.

FIG. 1 illustrates a polishing apparatus, according to some embodiments.

FIG. 2 illustrates a database of training data for image processing, according to some embodiments.

FIG. 3 illustrates a flowchart of a method for training models to characterize film thicknesses on semiconductor substrates, according to some embodiments.

FIG. 4 illustrates a flowchart of a process for performing the simulation of light measurements taken from the film, according to some embodiments.

FIG. 5 illustrates an example of a semiconductor substrate design with a linear film thickness profile, according to some embodiments.

FIG. 6 illustrates a graph from the simulation process for generating training data, according some embodiments.

FIG. 7 illustrates a neural network used as a part of the controller for the polishing apparatus, according to some embodiments.

FIG. 8 illustrates an exemplary computer system, in which various embodiments may be implemented.

### DETAILED DESCRIPTION

Described herein are embodiments for generating simulated data for training a model to estimate thickness from surface images of a semiconductor film. A machine-learning model may be used to estimate a film thickness from a spectral image captured from a semiconductor substrate during processing. Instead of using actual measurements from physical substrates to train the model, simulated images may be generated for a wide variety of predefined thickness profiles. Simulated training data may be rapidly generated by receiving a film thickness profile representing a film on a semiconductor substrate design. A light source may be simulated being reflected off of the film on the semiconductor substrate and being captured by a camera. The spectral data captured by the camera may be converted into one or more images for a wafer having the film thickness profile. The images may then be labeled with the film thickness profile for training a machine-learning model.

Thin-film thickness measurements from dry metrology systems are used in CMP processing because of the variability in the polishing rate that occurs in CMP processes. Such dry metrology measurement techniques often use a spectrographic or ellipsometric approach in which variables in an optical model of a film stack are fit to the collected measurements. Such measurement techniques typically require precise alignment of a sensor to a measurement spot of the substrate to ensure that the model is applicable to the collected measurements. Therefore, measuring a large number of points on the substrate can be time-consuming, and collecting a high-resolution thickness profile is not feasible.

However, the usage of machine learning can enable measurement of a thickness of a film on a substrate with reduced time. By training a deep neural network using images of dies from a substrate and associated thickness measurements, film thicknesses of dies can be measured by applying an input image to the neural network. Aside from the thickness inferences, this technique can be used to classify levels of residue on the substrate using the image segmentation.

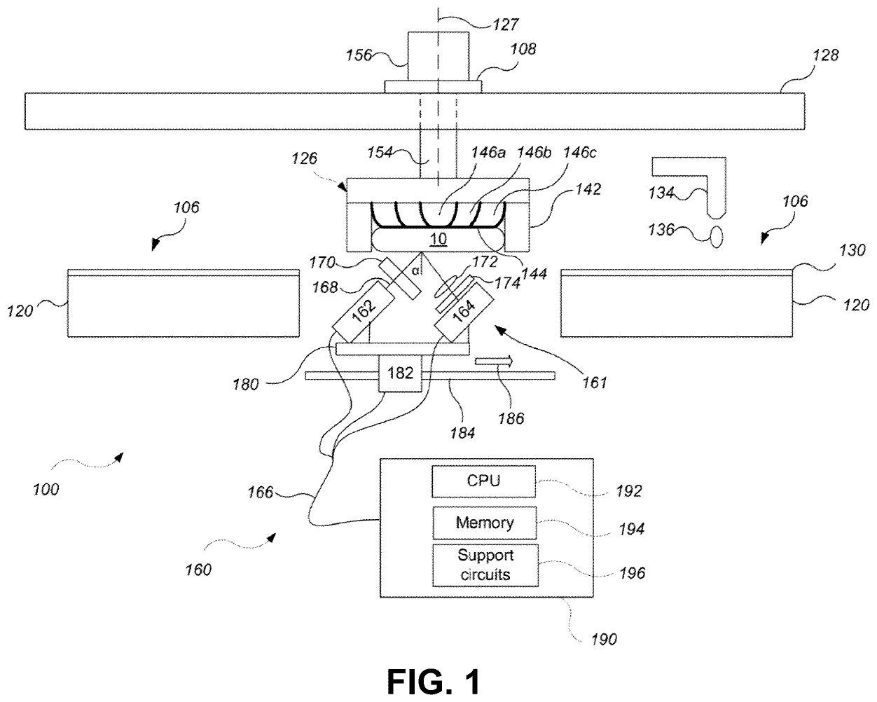

FIG. 1 illustrates a polishing apparatus, according to some embodiments. The polishing apparatus 100 may include one or more carrier heads 126 configured to carry a substrate 10, one or more polishing stations 106, and/or a transfer station to load substrates to and unload substrates from a carrier head. A polishing station 106 may include a polishing pad 130 supported on a platen 120. The polishing pad 130 may be a two-layer polishing pad with an outer polishing layer and a softer backing layer.

A carrier head 126 may be suspended from a support 128 and may be movable between the polishing stations 106. In some embodiments, the support 128 may include an overhead track, and the carrier head 126 may be coupled to a carriage 108 that is mounted to the track so that the carriage 108 and other carriages (not shown) may be selectively moved between the polishing stations 106 and the transfer station. Alternatively, in some implementations, the support 128 may include a rotatable carousel, and rotation of the rotatable carousel may move the carrier heads 126 simultaneously along a circular path.

Each polishing station 106 of the polishing apparatus 100 may include a port, e.g., at the end of an arm 134, to dispense polishing liquid 136, such as abrasive slurry, onto the polishing pad 130. Each polishing station 106 of the polishing apparatus 100 may also include a pad conditioning apparatus to abrade the polishing pad 130 to maintain the polishing pad 130 in a consistent abrasive state.

The carrier head 126 may be operable to hold a substrate 10 against the polishing pad 130. Each carrier head 126 may have independent control of the polishing parameters, such as a pressure associated with each respective substrate. In particular, each carrier head 126 may include a retaining ring 142 to retain the substrate 10 below a flexible membrane 144. Each carrier head 126 may also include a plurality of independently controllable pressurizable chambers defined by the membrane, e.g., three chambers 146a-146c, which may apply independently controllable pressures to associated zones on the flexible membrane 144 and thus on the substrate 10. Although only three chambers are illustrated in FIG. 1 for ease of illustration, there may be one or two chambers, or four or more chambers (e.g., five chambers).

Each carrier head 126 may be suspended from the support 128 and may be connected by a drive shaft 154 to a carrier head rotation motor 156 so that the carrier head may rotate about an axis 127. Optionally each carrier head 126 may oscillate laterally, e.g., by driving the carriage 108 on a track, or by the rotational oscillation of the carousel itself. In operation, the platen may be rotated about its central axis, and each carrier head may be rotated about its central axis 127 and translated laterally across the top surface of the polishing pad.

A controller 190, such as a programmable computer, may be connected to each motor to independently control the rotation rate of the platen 120 and the carrier heads 126. The controller 190 may include a central processing unit (CPU) 192, a memory 194, and support circuits 196, e.g., input/output circuitry, power supplies, clock circuits, cache, and the like. The memory may be connected to the CPU 192. The memory may be a non-transitory computable readable medium, and may be one or more readily available memory such as random access memory (RAM), read-only memory (ROM), floppy disk, hard disk, or another form of digital storage. In addition, although illustrated as a single computer, the controller 190 could be a distributed system, e.g., including multiple independently operating processors and memories.

The polishing apparatus 100 may also include an in-line (also referred to as in-sequence) optical metrology system 160. An imaging system of the in-line optical metrology system 160 may be positioned within the polishing apparatus 100, but need not perform measurements during the polishing operation. Rather, measurements may be collected between polishing operations, e.g., while the substrate is moved from one polishing station to another, or during pre-polishing or post-polishing operations, such as while the substrate is being moved from the transfer station to a polishing station or vice versa. In addition, the in-line optical metrology system 160 may be positioned in a fab interface unit or a module accessible from the fab interface unit to measure a substrate after the substrate is extracted from a cassette but before the substrate is moved to the polishing unit, or after the substrate has been cleaned but before the substrate is returned to the cassette.

The in-line optical metrology system 160 may include a sensor assembly 161 that provides the imaging of the substrate 10. The sensor assembly 161 may include a light source 162, a light detector 164, and/or circuitry 166 for sending and receiving signals between the controller 190 and the light source 162 and light detector 164.

The light source 162 may be operable to emit white light. In some embodiments, the white light emitted may include light having wavelengths of between about 200 nm and about 800 nm. A suitable light source may include an array of white-light light-emitting diodes (LEDs), a xenon lamp, and/or a xenon mercury lamp. The light source 162 may be oriented to direct light 168 onto the exposed surface of the substrate 10 at a non-zero angle of incidence a. The angle of incidence may be, for example, between about 300 and about 750 (e.g., 50°).

The light source may illuminate a substantially linear elongated region that spans the width of the substrate 10. For example, the light source 162 may include optics, such as a beam expander to spread the light from the light source into an elongated region. Alternatively or additionally, the light source 162 may include a linear array of light sources. The light source 162 itself, and the region illuminated on the substrate, may elongate and have a longitudinal axis parallel to the surface of the substrate.

A diffuser 170 may be placed in the path of the light 168, or the light source 162 may include a diffuser, to diffuse the light before it reaches the substrate 10.

The detector 164 may be a camera that may be sensitive to light from the light source 162. The camera may include an array of detector elements. For example, the camera may include a CCD array. In some embodiments, the array may be a single row of detector elements. For example, the camera may be a line-scan camera. The row of detector elements may extend parallel to the longitudinal axis of the elongated region illuminated by the light source 162. Where the light source 162 includes a row of light-emitting elements, the row of detector elements may extend along a first axis parallel to the longitudinal axis of the light source 162. A row of detector elements may include 1024 or more elements.

The camera 164 may be configured with appropriate focusing optics 172 to project a field of view of the substrate onto the array of detector elements. The field of view may be long enough to view the entire width of the substrate 10, e.g., 150 to 300 mm long. The camera 164, including associated optics 172, may be configured such that individual pixels correspond to a region having a length equal to or less than about 0.5 mm. For example, assuming that the field of view may be about 200 mm long and the detector 164 includes 1024 elements, then an image generated by the line-scan camera may have pixels with a length of about 0.5 mm. To determine the length resolution of the image, the length of the field of view (FOV) may be divided by the number of pixels onto which the FOV is imaged to arrive at a length resolution.

The camera 164 may be also be configured such that the pixel width may be comparable to the pixel length. For example, an advantage of a line-scan camera may be its very fast frame rate. The frame rate may be at least 5 kHz. The frame rate may be set at a frequency such that as the imaged area scans across the substrate 10, the pixel width may be comparable to the pixel length, e.g., equal to or less than about 0.3 mm.

The light source 162 and the light detector 164 may be supported on a stage 180. When the light detector 164 includes a line-scan camera, the light source 162 and camera 164 may be movable relative to the substrate 10 such that the imaged area may scan across the length of the substrate. In particular, the relative motion may be in a direction parallel to the surface of the substrate 10 and perpendicular to the row of detector elements of the line-scan camera 164.

In some implementations, the stage 182 may be stationary, and the support for the substrate may move. For example, the carrier head 126 may move, e.g., either by motion of the carriage 108 or by rotational oscillation of the carousel. The robot arm holding the substrate in a factory interface unit may also move the substrate 10 past the line-scan camera 182. In some embodiments, the stage 180 may be movable while the carrier head or robot arm remains stationary for the image acquisition. For example, the stage 180 may be movable along a rail 184 by a linear actuator 182. In either case, this permits the light source 162 and the camera 164 to stay in a fixed position relative to each other as the area being scanned moves across the substrate 10.

A possible advantage of having a line-scan camera and light source that move together across the substrate may be that, e.g., as compared to a conventional 2D camera, the relative angle between the light source and the camera remains constant for different positions across the wafer. Consequently, artifacts caused by variation in the viewing angle may be reduced or eliminated. In addition, a line scan camera may eliminate perspective distortion, whereas a conventional 2D camera may exhibit inherent perspective distortion, which then may need to be corrected by an image transformation. The sensor assembly 161 may include a mechanism to adjust vertical distance between the substrate 10 and the light source 162 and detector 164. For example, the sensor assembly 161 may include an actuator to adjust the vertical position of the stage 180.

Optionally a polarizing filter 174 may be positioned in the path of the light, e.g., between the substrate 10 and the detector 164. The polarizing filter 174 may include a circular polarizer (CPL). A typical CPL may be a combination of a linear polarizer and quarter-wave plate. Proper orientation of the polarizing axis of the polarizing filter 174 may reduce haze in the image and sharpen or enhance desirable visual features.

Assuming that the outermost layer on the substrate is a semitransparent layer, e.g., a dielectric layer, the color of light detected at detector 164 depends on, e.g., the composition of the substrate surface, substrate surface smoothness, and/or the amount of interference between light reflected from different interfaces of one or more layers (e.g., dielectric layers) on the substrate. As noted above, the light source 162 and light detector 164 may be connected to a computing device, e.g., the controller 190, operable to control their operation and receive their signals. The computing device that performs the various functions to convert the color image to a thickness measurement, may be considered part of the metrology system 160.

A color image captured by the system described above may be fed to an image processing algorithm to generate a thickness measurement for the die shown in the color image. The image may be used as input data to an image processing algorithm that has been trained, e.g., by a supervised deep learning approach, to estimate a layer thickness based on a color image. The supervised deep learning-based algorithm may establish a model between color images and thickness measurements. The image processing algorithm may include a neural network as the deep learning-based algorithm.

An intensity value for each color channel of each pixel of the color image may be entered into the image processing algorithm, e.g., into the input neurons of the neural network. Based on this input data, a layer thickness measurement may be calculated for the color image. Thus, input of the color image to the image processing algorithm result in output of an estimated thickness. This system may be used as high-throughput and economical solution for the low-cost memories and other applications. Aside from the thickness inferences, this technique may also be used to classify levels of residue on the substrate using the image segmentation.

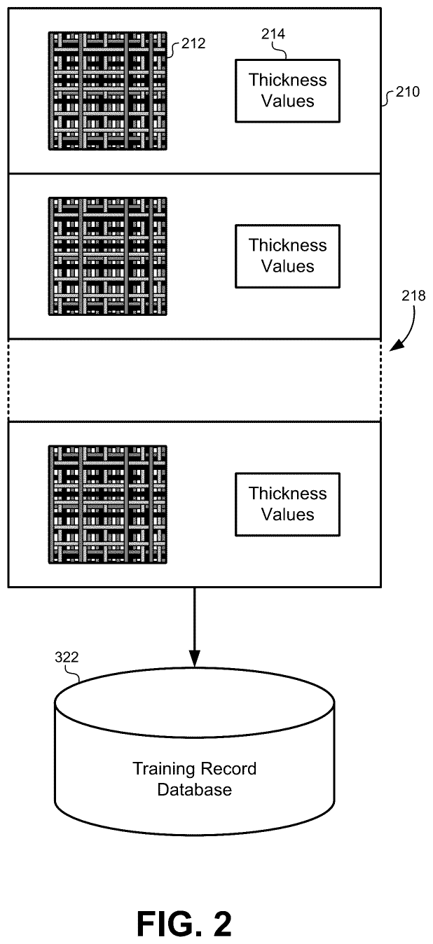

FIG. 2 illustrates a database 220 of training data for image processing, according to some embodiments. In order to train the image processing algorithm, e.g., the neural network, using the supervised deep learning approach, labeled images may be collected and stored. For example, the database 220 may store individual records 210, each of which may correspond to a training pair. Each training pair may include an image 212 representing the substrate and a thickness value 214 for a film on the substrate. The deep learning-based algorithm, e.g., the neural network, may then be trained using a combined data set 218 comprising a plurality of individual records 210. The thickness value 214 in each of the individual records 210 may be used as a label for the corresponding image 212 for training the model.

In order for this machine-learning method to work effectively, the model may benefit from being exhaustively and accurately trained to recognize a thickness based on an input image. Accurate training of the model typically requires many thousands of labeled images. These images should ideally represent a diversity of different film materials, film thicknesses, film patterns, and/or other design characteristics that may vary between different substrates. A large and diverse training data set ensures that the neural network is able to accurately estimate a thickness based on the different variations that may occur within a substrate or between different substrates.

However, a technical challenge exists when generating a representative and extensive data set to train the model. Specifically, generating the training data is a time-consuming and resource-intensive process. For example, the combined data set 218 comprising thousands of images may each require an individual image to be captured of the physical substrate. In order to label this data, the substrate may then be subject to a metrology process in order to measure an accurate thickness of the substrate corresponding to each image. Metrology measurements typically require a separate metrology station that may require minutes or even hours of time to accurately characterize and measure surface film thicknesses on a substrate. Additionally, using actual images of real wafers requires physical substrates to be first manufactured and then used as calibration substrates for training data.

For example, either before or after the initial calibration image may be collected, ground truth thickness measurements may be collected at multiple locations on a calibration substrate using a high-accuracy metrology system, e.g., an in-line or stand-alone metrology system. The high-accuracy metrology system may be a dry optical metrology system. The ground truth measurement may come from offline reflectometry, ellipsometry, scatterometry or more advanced TEM measurements, although other techniques may be suitable. For example, for each individual region on each calibration substrate, a color calibration image may be collected with the in-line sensor of the optical metrology system 160. Each color calibration image may be associated with the “ground truth” thickness measurement for the corresponding die on the calibration substrate from the metrology data. The images and associated ground truth thickness measurements may be stored in a database. For example, the data may be stored as records with each record including a calibration image and a ground truth thickness measurement. The images 212 and associated ground truth thickness values 214 may be stored in the database 220.

The deep learning-based algorithm, e.g., the neural network, may then train using the combined data set 218. The thickness measurements corresponding to the center of die measured from metrology tool may be used as a label for the input image while training the model. For example, adequate training of the model may use about 50,000 images collected from at least five dies on different substrates that have a wide range of film thicknesses and materials. That is, each calibration substrate may be scanned by the line-scan camera of the in-line optical metrology system 160 to generate an initial calibration image, and the initial calibration image may be divided into a plurality of color images of the individual regions on the calibration substrate. Therefore, using images of real wafers and labeling those images with metrology data can require too much time and too many different substrates in order to generate adequate training data in an efficient manner.

The embodiments described herein solve these and other technical problems by using a model to simulate the generation of training data. For example, mathematical and/or physical models of the light source, the reflection of the emitted light from the substrate film, and the conversion of the spectral response of the film into pixel values by the camera may be simulated. Different thickness profiles, film materials, light source characteristics, camera types, and/or other process parameters may be used to generate images representing virtual wafers having these different characteristics. Since the film thickness is known apriori as part of generating the wafer, the corresponding image may be labeled with the known film thickness and used to train the neural network. This neural network may then later be used to estimate or calculate a thickness based on an image of a real wafer.

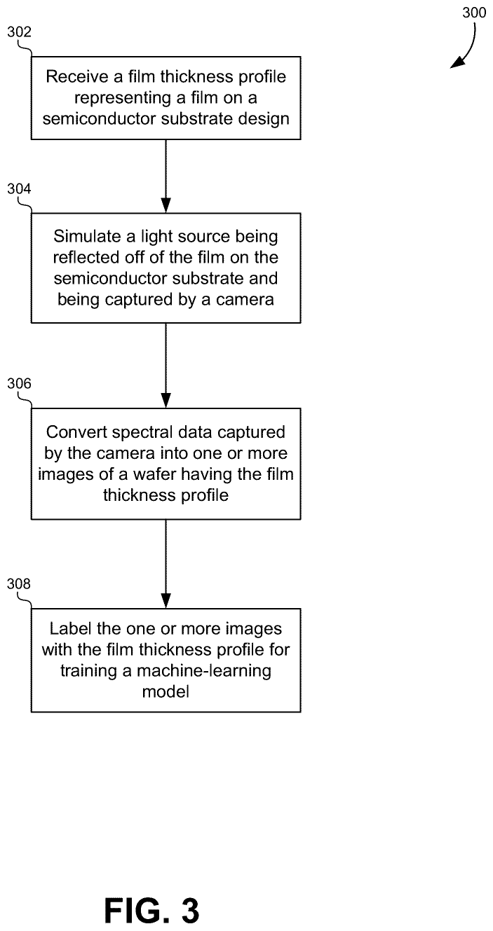

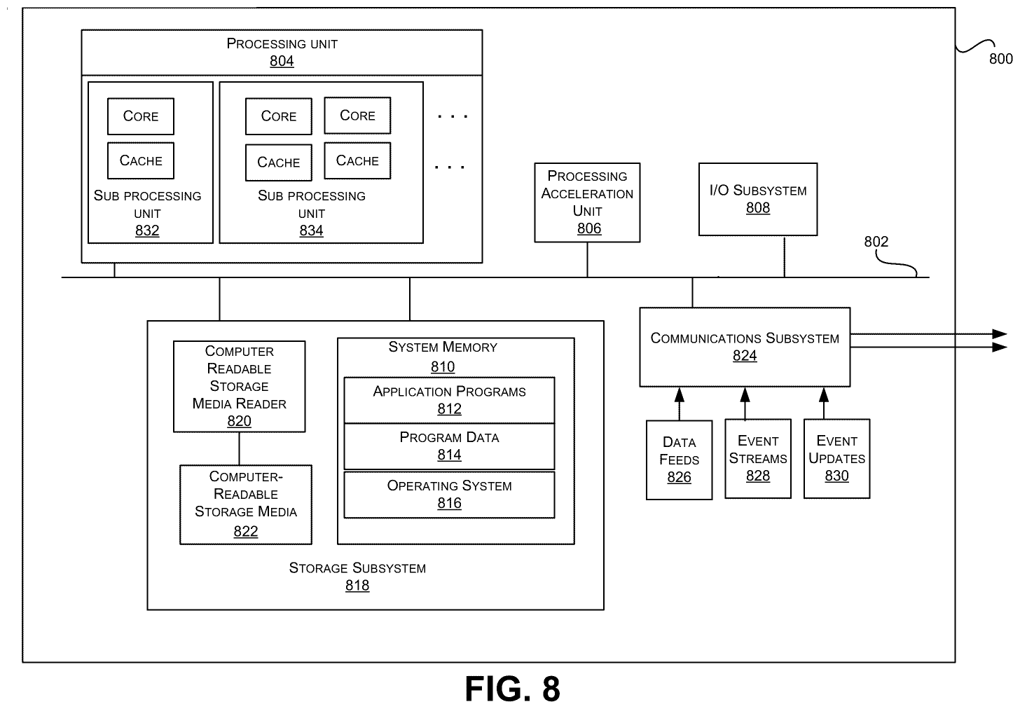

FIG. 3 illustrates a flowchart 300 of a method for training models to characterize film thicknesses on semiconductor substrates, according to some embodiments. This method may be executed by a computer system that includes one or more processors and one or more memory devices. The memory device(s) may store instructions that cause the one or more processors to execute the operations of flowchart 300. For example, the one or more memory devices may include one or more non-transitory computer-readable media configured to store processor instructions. FIG. 8 below illustrates a computer system that may be used to execute these operations.

The method may include receiving a film thickness profile representing a film on a semiconductor substrate design (302). The film thickness profile may include any data set characterizing a thickness of various locations on a semiconductor substrate. For example, the thickness profile may include a measurement along a radial line extending out from a center of the semiconductor substrate to a periphery of the semiconductor substrate. Other embodiments may use a diameter line extending from one edge of the substrate to another, exiting through a center point of the substrate. Some embodiments may use circular measurements of the thicknesses of the substrate at various radii extending out from a center of the substrate. Some embodiments may use a random or distributed sampling of thickness measurements at various points on the substrate. The film thickness profile may be taken from any head zone in the semiconductor processing station and may include any arbitrary shape, such as radial, as azimuthal, and/or spiral line profiles. Some embodiments are not limited to 1-D images such as line profiles, and may instead use 2-D images having any arbitrary shape or size.

The thickness profile may be represented using a set of data point pairs. For example, the thickness profile may include a data point pair may include a location coordinate, distance, or pixel count/number on the semiconductor substrate along with a thickness measurement. A collection of these data point pairs may be stored together to form a thickness profile that indicates a thickness of the semiconductor substrate along the line, diameter, radius, or other locations on the substrate.

The film on the semiconductor substrate may include any type of layer or film deposited on a substrate during a manufacturing process. The film may include silicon dioxide or other oxide films. The film may also include nitride films. Other layers that may form the film may include metal layers, photoresist layers, mask layers, semiconductor layers, silicon layers, and so forth. These layers are provided only by way of example, and any film type may be simulated to be present on the surface of the semiconductor substrate. Some embodiments may also characterize the film thickness profile not only by a top-layer film, but also by one or more underlying film layers that may be underneath the top-layer film. Because the underlying film layers may also affect the reflectance of the light spectra from the light source, different combinations of top-layer films and underlying films may be used to generate different thickness profiles. Therefore, each film thickness profile may be specific to not only a top-layer film material, but also to combinations of the top-layer film materials with different film materials underneath the top-layer film. Some embodiment may also generate film thickness profiles that are specific to individual semiconductor substrate designs, such as different circuit or layout patterns in the film.

The semiconductor substrate design may be represented by an actual physical substrate design, or from a model or design file representing the design. In contrast to previous solutions, these embodiments do not require an actual physical semiconductor substrate on which to perform measurements to measure the film thickness profile. Instead, a design file or other design representation of the semiconductor substrate may be used for the simulation. For example, the semiconductor substrate design may include characteristics such as a film material, a film thickness, a film deposition process, a film pattern, underlying film materials, a semiconductor substrate size, and so forth. In some embodiments, the semiconductor substrate design may simply be represented using a film material type with a thickness. The semiconductor substrate design may also include other semiconductor features, such as scribe lines and other complex patterns on the semiconductor substrate.

The method may also include simulating a light source being reflected off of the film on the semiconductor substrate and being captured by a camera (304). As described above, some semiconductor processing stations, such as processes that planarize a semiconductor substrate using chemical mechanical polishing, may measure film thickness by directing a light to a surface of the substrate and measuring the spectral response of the reflected light from the top-layer film. The reflected light spectra may be captured by a camera and converted into digital pixels. The pixels of this image may then be analyzed to determine a film thickness in real time as the process is taking place. The images may be analyzed using a machine-learning model, such as a neural network, that receives the image as an input and generates an estimated thickness as an output. Instead of training this model using actual thickness measurements from physical semiconductor substrates, these embodiments simulate the light source being reflected off of the film on the semiconductor substrate and being captured by the camera.

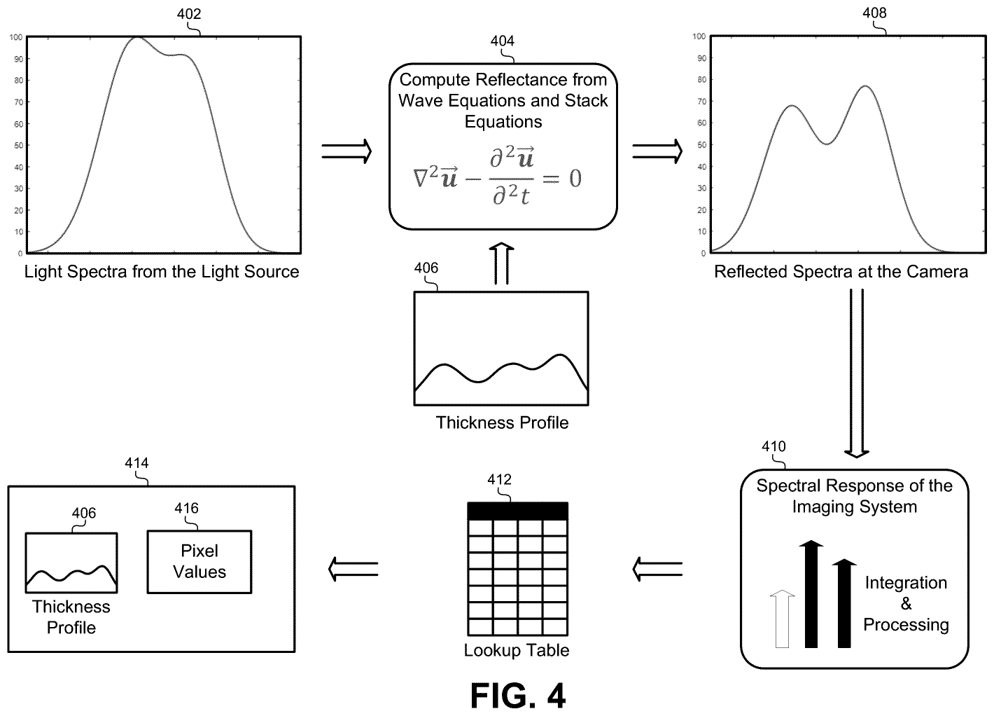

FIG. 4 illustrates a flowchart of a process for performing the simulation of light measurements taken from the film, according to some embodiments. First, a light spectra from the light source 402 may be provided to the simulation process 404. The light spectra may include a wavelength of light provided by the light source. For example, some embodiments may simulate a laser light using a specific wavelength or wavelength range being directed at the surface of the film. The light spectra may include a single wavelength, and/or a distribution of wavelengths as illustrated in FIG. 4. Some embodiments may also consider other characteristics of the light source, such as an intensity of the light source, any filters applied to the light source, an incident angle of the light source relative to the top-layer film, and so forth.

In addition to the light spectra from the light source 402, the film thickness profile 406 may be provided to the simulation process 404. In some embodiments, the film type and the light spectra from the light source 402 may be held constant for a number of different film thickness profiles 406. Although not shown explicitly in FIG. 4, other process parameters may be provided to the simulation process, such as a film material, underlying film layers, a semiconductor substrate size, and so forth. The film thickness profile 406 may be changed for each simulation, thereby providing a plurality of different simulation results for each set of the processing conditions and film types. Some embodiments may generate the film thickness profile 406 as a combination of Gaussian signals. Other embodiments may generate the film thickness profile 406 based on previous measurements of actual physical film thicknesses from real substrates. Some embodiments may generate the film thickness profile 406 randomly to generate a wide variety of continuous or semicontinuous thickness profile curves. For example, the film thickness profile may be varied from between 0 Å to about 10,000 Å to simulate different thickness profiles.

After these inputs are received, the simulation process 404 may simulate and compute the reflection of the light source from the top-layer film. Because the physical properties the film are known to the simulation process 404, standard thin-film interference formulas related to stack properties may be used to calculate the reflectance of the light spectra from the light source 402. For example, the optical properties of each film material (e.g., an oxide film, a nitride film, etc) will be known based on the properties from the semiconductor substrate design. These physical properties may be used in the standard thin-film interference formulas used in electromagnetic modeling of the film to calculate an amount of light reflected towards the camera, along with the spectra of the light reflected. The output of the simulation process 404 may include a reflected spectra 408 of light to be received by the camera of the measurement system.

In some embodiments, noise or other signals may be added to the simulation process. For example, signal noise may be added to the light spectra from the light source 402 or to the reflected spectra 408 to simulate noise that may be present during, for example, a chemical mechanical polishing process. Some embodiments may also add simulated defects to the thickness profile 406. The simulated defects may include defects in an underlying film layer, foreign materials embedded in the film layer, and/or other surface defects. The simulated defects may also include anomalies such as film delamination, voids in the film, and so forth.

Turning back briefly to FIG. 3, the method may additionally include converting spectral data captured by the camera into one or more images for a wafer having the film thickness profile (306). At this stage, the spectra output of the light source may have been converted into a spectral input for the camera using the simulation process 404, the film thickness profile 406, and/or other physical properties of the film and/or semiconductor substrate design in FIG. 4. A camera simulation 410 may then convert the spectral response that would be captured by the camera into pixel values output from the camera. For example, some embodiments may model the operation of the camera by using a lookup table 412 that translates light spectra values into RGB pixel values 416. The lookup table 412 may be based on known physical and operational properties of the camera. Each spectral wavelength may be translated into RGB pixel values 416 to generate a simulated image captured by the camera.

This simulated image approximates the actual image that would be captured by the camera during a real-world physical process. However, the simulated image may be generated much faster and without requiring the actual use and processing of a semiconductor substrate. The physical properties of the camera may be known and provided as inputs to this process. For example, the spectral response for each wavelength may be determined for the camera, and this spectral response of the camera may be used to convert the reflected light into RGB data by populating the lookup table 412. Therefore, the lookup table 412 may represent a model of the operation of the camera.

Turning back again to FIG. 3, the method may additionally include labeling the one or more images with the film thickness profile for training a machine-learning model (308). The pixel values 416 in FIG. 4 of the image and the film thickness profile 406 may then be associated with each other to form training pairs 414. The training pairs may include pixel values or an image along with a thickness associated with the pixel values or the image. The training pair 414 may be one of a plurality of training pairs that are used to train the neural network described herein. Each film thickness profile 406 may be used to generate a training pair for each thickness value in the film thickness profile 406. As described above, each thickness measurement in the film thickness profile 406 may be associated with a location on the semiconductor substrate design.

After the simulation, each thickness measurement in the film thickness profile 406 may also be associated with an image of that location on the semiconductor substrate design. Thus, simulations using a single film thickness profile 406 may generate a plurality of different training pairs 414. Therefore, the one or more images generated by this process for the wafer having the film thickness profile may be used to label the one or more images with individual thicknesses from the film thickness profile at different locations on the semiconductor substrate design. When multiple simulations are run using different film thickness profiles 406, many hundreds or thousands of training pairs 414 may be generated very quickly to train the neural network to recognize film thicknesses from reflected images. In some embodiments, a pixel value may be associated with a range of thicknesses (e.g., a range of Angstroms) rather than a single thickness. Some embodiments may alternatively or additionally output a range of thickness nonuniformity in relation to a reference point rather than an absolute thickness. This allows the simulation to compensate for sublayer variations. Note that using the thickness profile 406 is only one example for generating training labels, particularly where the process is predicting multiple, continuous thickness values along the profile. Other embodiments may also use a single thickness value per image or line profile, and are thus not limited to continuous thickness profiles. Alternatively, multiple discrete thickness values may be used when labeling the data.

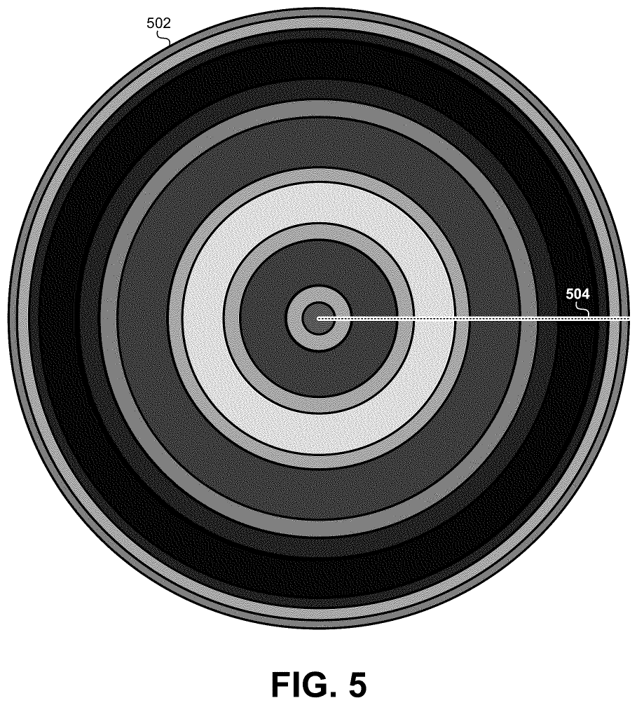

FIG. 5 illustrates an example of a semiconductor substrate design 502 with a linear film thickness profile 504, according to some embodiments. In this example, the semiconductor substrate design 502 may include design specifications for a semiconductor substrate with a particular film material formed as a top layer on the semiconductor substrate. The film thickness may be generated using any of the techniques described above. By way of illustration, the film thicknesses are represented by different color shadings in FIG. 5. The film thickness profile 504 may be generated by capturing a series of measurements along a radial line that extends from the center of the semiconductor substrate to a periphery of the substrate. Note that this linear film thickness profile 504 is provided only by way of example and is not meant to be limiting. Any of the other profiles (e.g. linear, circular, azimuthal, spiral, etc.) described herein may be used without limitation.

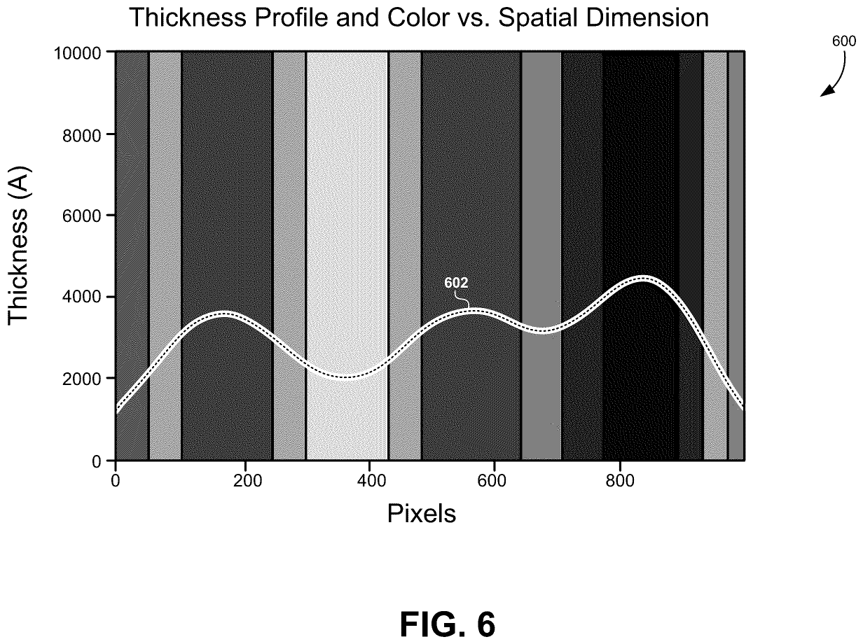

FIG. 6 illustrates a graph 600 from the simulation process for generating training data, according some embodiments. One advantage of the simulation process may be the ability to use images with different color characteristics. For example, monochrome images, multispectral images, and/or hyperspectral images may all be used and generated by the simulation process. The horizontal axis on the graph 600 represents a pixel number corresponding to the linear film thickness profile 504 in FIG. 5. Thus, the linear film thickness profile 504 may vary from, for example, a few hundred pixels to a few thousand pixels in length. The film thickness profile 504 may therefore be much smaller than the full set of metrology data that is typically used to characterize the film thickness on a substrate, which typically creates a full rectangular image of the substrate. This may greatly reduce the memory requirements and/or processing requirements for considering different substrate materials and thickness profiles. Using the pixel number from the horizontal axis, the specific location on the semiconductor substrate may be calculated using the known the spatial resolution of each pixel.

The vertical axis of the graph 600 corresponds to a thickness of the semi conductor substrate at each specific location. The curve 602 illustrates the simulated result of the thickness for each of the pixel locations on the horizontal axis. The background colors of the graph 600 correspond to the colors used to characterize the thickness of the semiconductor substrate design 502 in FIG. 5.

An advantage of using the simulation process described above to rapidly generate training data for the neural network may include the ability to train the neural network to recognize anomalous conditions in addition to recognizing a thickness. For example, a simulated noise signal may be generated and mixed with any of the spectral responses used in the simulation. The training data generated from the simulated noise signal may be used to model real-world noise anomalies. Thus, the neural network may be trained to recognize when the noise level of a physical process increases beyond a threshold amount. By recognizing this increased noise level, the model may generate an output that indicates that, for example, a polishing slurry needs to be changed; the optical windows, lenses, or light filters need to be cleaned or exchanged; and/or other system maintenance may need to be performed to improve the data captured by the imaging system.

In another example, a simulated defect, such as a foreign material embedded in the top-layer film or in an underlying layer may be provided as an input to the simulation process. This allows the neural network to be trained to recognize a defect in the film based on an image received by the imaging system. The neural network may generate an output that indicates a location of the defect. This may allow the source of the defect to be recognized early in the manufacturing process.

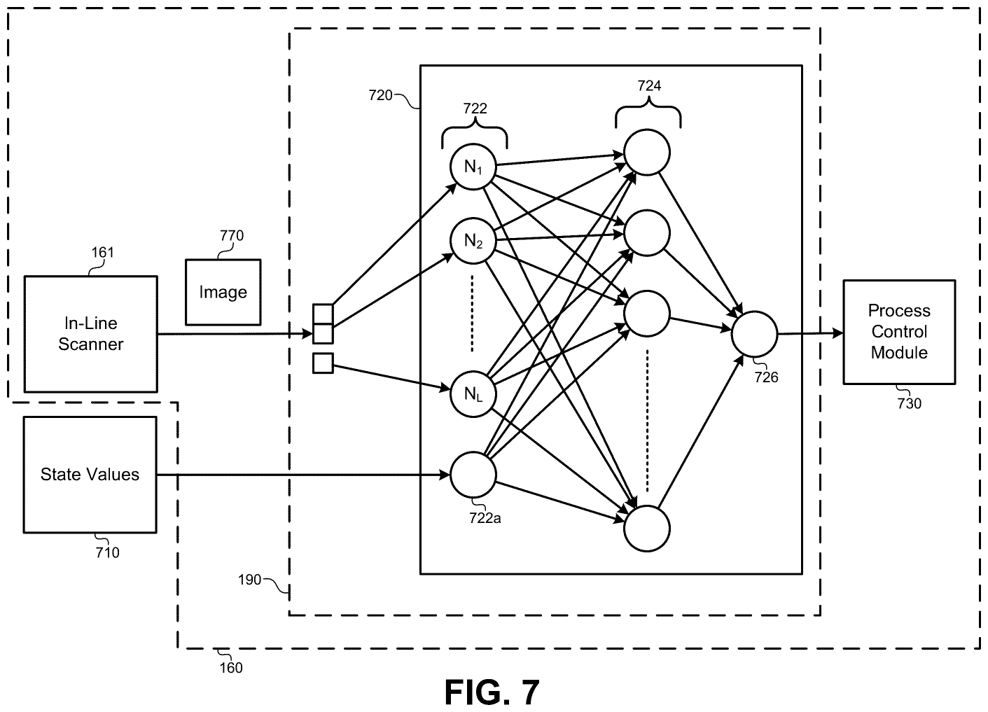

FIG. 7 illustrates a neural network 720 used as a part of the controller 190 for the polishing apparatus 100, according to some embodiments. The neural network 720 may be a deep neural network developed for regression analysis of RGB intensity values of the input images from the calibration substrate and the ground truth thickness measurements to generate a model to predict the layer thickness of a region of a substrate based on a color image of that region.

The neutral network 720 may include a plurality of input nodes 722. The neural network 720 may include an input node for each channel associated with each pixel of the input image, a plurality of hidden nodes 724 (also called “intermediate nodes” below), and an output node 726 that may generate the layer thickness measurement value. In a neural network having a single layer of hidden nodes, each hidden node 724 may be coupled to each input node 722, and the output node 726 may be coupled to each hidden node 720. However, as a practical matter, the neural network for image processing may be likely to have many layers of hidden nodes 724. In general, a hidden node 724 may output a value that a non-linear function of a weighted sum of the values from the input nodes 722 or prior layers of hidden nodes to which the hidden node 724 may be connected.

However, neural network 720 may optionally include one or more other input nodes, e.g., node 722 a, to receive other data. This other data could be from a prior measurement of the substrate by the in-situ monitoring system, e.g., pixel intensity values collected from earlier in the processing of the substrate, from a measurement of a prior substrate, e.g., pixel intensity values collected during processing of another substrate, from another sensor in the polishing system, e.g., a measurement of a temperature of the pad or substrate by a temperature sensor, from a polishing recipe stored by the controller that may be used to control the polishing system, e.g., a polishing parameter such as carrier head pressure or platen rotation rate use for polishing the substrate, from a variable tracked by the controller, e.g., a number of substrates since the pad was changed, or from a sensor that need not be part of the polishing system, e.g., a measurement of a thickness of underlying films by a metrology station. This permits the neural network 720 to take into account other processing or environmental variables in the calculation of the layer thickness measurement value.

The thickness measurement generated at the output node 726 may be fed to a process control module 730. The process control module may adjust, based on the thickness measurements of one or more regions, the process parameters, e.g., carrier head pressure, platen rotation rate, etc. The adjustment may be performed for a polishing process to be performed on the substrate or a subsequent substrate.

Before being used for, e.g., substrate measurements, the neutral network 720 may be trained using the simulated data described in detail above. As part of a training procedure, the controller 190 may receive a plurality of simulated training images generated from the simulation process. Each simulated image may include multiple intensity values, e.g., an intensity value for each channel, for each pixel of the simulated image. The controller also may receive a characterizing value, e.g., thickness, for each calibration image. The thickness and the image values may be received as a training pairs described above. The plurality of simulated images may be generated from, for example, greater than or about 10 simulations, greater than or about 20 simulations, greater than or about 50 simulations, greater than or about 75 simulations, greater than or about 100 simulations, greater than or about 150 simulations, greater than or about 200 simulations, greater than or about 250 simulations, greater than or about 300 simulations, greater than or about 400 simulations, greater than or about 500 simulations, greater than or about 1000 simulations, and so forth. As of the configuration procedure for the neural network 720, the neural network 720 may be trained using the simulated image and the characteristic value for semiconductor substrate design.

For example, V may correspond to one of the simulated images and may thus be associated with a thickness value or thickness range. While the neural network 720 is operating in a training mode, such as a backpropagation mode, the values (v1, v2, . . . , vL) may be fed to the respective input nodes N1, N2 . . . NL while the characteristic value thickness value or thickness range may be fed to the output node 726 as a characteristic value. This may be repeated for each pixel and thickness value combination. This process sets the values for the internal node weights of the neural network 720.

The system may now be ready for operation to estimate thicknesses from live images captured from the semiconductor processing chamber during actual process. An actual image measured from a substrate using the in-line monitoring system 160 may be captured in real time. The captured image may be represented by a column matrix S=(i1, i2, . . . , IL), where ij represents the intensity value at the jth intensity value out of L intensity values, with L=3n when the image includes a total of n pixels and each pixel may include multiple channels. While the neural network 720 may be used in an inference mode, these values (S1, S2, . . . , SL) are fed as inputs to the respective input nodes N1, N2, . . . NL. As a result, the neural network 720 may generates a characteristic value, e.g., a layer thickness or thickness range, at the output node 726.

The architecture of the neural network 720 may vary in depth and width. For example, although the neural network 720 is shown with a single column of intermediate nodes 724, it may include multiple columns. The number of intermediate nodes 724 may be equal to or greater than the number of input nodes 722. As noted above, the controller 190 may associate the various images with different dies (see FIG. 2) on the substrate. The output of each neural network 720 may be classified as belonging to one of the dies based on the position of the sensor on the substrate at the time the image is collected. This permits the controller 190 to generate a separate sequence of measurement values for each die.

In some implementations, the neural network 720 may be trained to take the underlying layer thickness from the stack into consideration during calculations, which may improve errors due to underlying variation in thickness measurements. The effect of the underlying thickness variation in the film stack may be alleviated by feeding the images of the thicknesses of the underlying layers as extra inputs to the model to improve the performance of the model.

Each of the methods described herein may be implemented by a computer system. Each step of these methods may be executed automatically by the computer system, and/or may be provided with inputs/outputs involving a user. For example, a user may provide inputs for each step in a method, and each of these inputs may be in response to a specific output requesting such an input, wherein the output is generated by the computer system. Each input may be received in response to a corresponding requesting output. Furthermore, inputs may be received from a user, from another computer system as a data stream, retrieved from a memory location, retrieved over a network, requested from a web service, and/or the like. Likewise, outputs may be provided to a user, to another computer system as a data stream, saved in a memory location, sent over a network, provided to a web service, and/or the like. In short, each step of the methods described herein may be performed by a computer system, and may involve any number of inputs, outputs, and/or requests to and from the computer system which may or may not involve a user. Those steps not involving a user may be said to be performed automatically by the computer system without human intervention. Therefore, it will be understood in light of this disclosure, that each step of each method described herein may be altered to include an input and output to and from a user, or may be done automatically by a computer system without human intervention where any determinations are made by a processor. Furthermore, some embodiments of each of the methods described herein may be implemented as a set of instructions stored on a tangible, non-transitory storage medium to form a tangible software product.

FIG. 8 illustrates an exemplary computer system 800, in which various embodiments may be implemented. The system 800 may be used to implement any of the computer systems described above. For example, the computer system 800 may be used to perform the simulation to generate training data described above. The computer system may also be used as the controller that executes the neural network and evaluates film thicknesses in real time as a semiconductor process is executed. As shown in the figure, computer system 800 includes a processing unit 804 that communicates with a number of peripheral subsystems via a bus subsystem 802. These peripheral subsystems may include a processing acceleration unit 806, an I/O subsystem 808, a storage subsystem 818 and a communications subsystem 824. Storage subsystem 818 includes tangible computer-readable storage media 822 and a system memory 810.

Bus subsystem 802 provides a mechanism for letting the various components and subsystems of computer system 800 communicate with each other as intended. Although bus subsystem 802 is shown schematically as a single bus, alternative embodiments of the bus subsystem may utilize multiple buses. Bus subsystem 802 may be any of several types of bus structures including a memory bus or memory controller, a peripheral bus, and a local bus using any of a variety of bus architectures. For example, such architectures may include an Industry Standard Architecture (ISA) bus, Micro Channel Architecture (MCA) bus, Enhanced ISA (EISA) bus, Video Electronics Standards Association (VESA) local bus, and Peripheral Component Interconnect (PCI) bus, which can be implemented as a Mezzanine bus manufactured to the IEEE P1386.1 standard.

Processing unit 804, which can be implemented as one or more integrated circuits (e.g., a conventional microprocessor or microcontroller), controls the operation of computer system 800. One or more processors may be included in processing unit 804. These processors may include single core or multicore processors. In certain embodiments, processing unit 804 may be implemented as one or more independent processing units 832 and/or 834 with single or multicore processors included in each processing unit. In other embodiments, processing unit 804 may also be implemented as a quad-core processing unit formed by integrating two dual-core processors into a single chip.

In various embodiments, processing unit 804 can execute a variety of programs in response to program code and can maintain multiple concurrently executing programs or processes. At any given time, some or all of the program code to be executed can be resident in processor(s) 804 and/or in storage subsystem 818. Through suitable programming, processor(s) 804 can provide various functionalities described above. Computer system 800 may additionally include a processing acceleration unit 806, which can include a digital signal processor (DSP), a special-purpose processor, and/or the like.

I/O subsystem 808 may include user interface input devices and user interface output devices. User interface input devices may include a keyboard, pointing devices such as a mouse or trackball, a touchpad or touch screen incorporated into a display, a scroll wheel, a click wheel, a dial, a button, a switch, a keypad, audio input devices with voice command recognition systems, microphones, and other types of input devices. User interface input devices may include, for example, motion sensing and/or gesture recognition devices such as the Microsoft Kinect® motion sensor that enables users to control and interact with an input device, such as the Microsoft Xbox® 360 game controller, through a natural user interface using gestures and spoken commands. User interface input devices may also include eye gesture recognition devices such as the Google Glass® blink detector that detects eye activity (e.g., ‘blinking’ while taking pictures and/or making a menu selection) from users and transforms the eye gestures as input into an input device (e.g., Google Glass®). Additionally, user interface input devices may include voice recognition sensing devices that enable users to interact with voice recognition systems (e.g., Siri® navigator), through voice commands.

User interface input devices may also include, without limitation, three dimensional (3D) mice, joysticks or pointing sticks, gamepads and graphic tablets, and audio/visual devices such as speakers, digital cameras, digital camcorders, portable media players, webcams, image scanners, fingerprint scanners, barcode reader 3D scanners, 3D printers, laser rangefinders, and eye gaze tracking devices. Additionally, user interface input devices may include, for example, medical imaging input devices such as computed tomography, magnetic resonance imaging, position emission tomography, medical ultrasonography devices. User interface input devices may also include, for example, audio input devices such as MIDI keyboards, digital musical instruments and the like.

User interface output devices may include a display subsystem, indicator lights, or non-visual displays such as audio output devices, etc. The display subsystem may be a cathode ray tube (CRT), a flat-panel device, such as that using a liquid crystal display (LCD) or plasma display, a projection device, a touch screen, and the like. In general, use of the term “output device” is intended to include all possible types of devices and mechanisms for outputting information from computer system 800 to a user or other computer. For example, user interface output devices may include, without limitation, a variety of display devices that visually convey text, graphics and audio/video information such as monitors, printers, speakers, headphones, automotive navigation systems, plotters, voice output devices, and modems.

Computer system 800 may comprise a storage subsystem 818 that comprises software elements, shown as being currently located within a system memory 810. System memory 810 may store program instructions that are loadable and executable on processing unit 804, as well as data generated during the execution of these programs.

Depending on the configuration and type of computer system 800, system memory 810 may be volatile (such as random access memory (RAM)) and/or non-volatile (such as read-only memory (ROM), flash memory, etc.) The RAM typically contains data and/or program modules that are immediately accessible to and/or presently being operated and executed by processing unit 804. In some implementations, system memory 810 may include multiple different types of memory, such as static random access memory (SRAM) or dynamic random access memory (DRAM). In some implementations, a basic input/output system (BIOS), containing the basic routines that help to transfer information between elements within computer system 800, such as during start-up, may typically be stored in the ROM. By way of example, and not limitation, system memory 810 also illustrates application programs 812, which may include client applications, Web browsers, mid-tier applications, relational database management systems (RDBMS), etc., program data 814, and an operating system 816. By way of example, operating system 816 may include various versions of Microsoft Windows®, Apple Macintosh®, and/or Linux operating systems, a variety of commercially-available UNIX® or UNIX-like operating systems (including without limitation the variety of GNU/Linux operating systems, the Google Chrome® OS, and the like) and/or mobile operating systems such as iOS, Windows® Phone, Android® OS, BlackBerry® 10 OS, and Palm® OS operating systems.

Storage subsystem 818 may also provide a tangible computer-readable storage medium for storing the basic programming and data constructs that provide the functionality of some embodiments. Software (programs, code modules, instructions) that when executed by a processor provide the functionality described above may be stored in storage subsystem 818. These software modules or instructions may be executed by processing unit 804. Storage subsystem 818 may also provide a repository for storing data used in accordance with some embodiments.

Storage subsystem 800 may also include a computer-readable storage media reader 820 that can further be connected to computer-readable storage media 822. Together and, optionally, in combination with system memory 810, computer-readable storage media 822 may comprehensively represent remote, local, fixed, and/or removable storage devices plus storage media for temporarily and/or more permanently containing, storing, transmitting, and retrieving computer-readable information.

Computer-readable storage media 822 containing code, or portions of code, can also include any appropriate media, including storage media and communication media, such as but not limited to, volatile and non-volatile, removable and non-removable media implemented in any method or technology for storage and/or transmission of information. This can include tangible computer-readable storage media such as RAM, ROM, electronically erasable programmable ROM (EEPROM), flash memory or other memory technology, CD-ROM, digital versatile disk (DVD), or other optical storage, magnetic cassettes, magnetic tape, magnetic disk storage or other magnetic storage devices, or other tangible computer readable media. This can also include nontangible computer-readable media, such as data signals, data transmissions, or any other medium which can be used to transmit the desired information and which can be accessed by computing system 800.

By way of example, computer-readable storage media 822 may include a hard disk drive that reads from or writes to non-removable, nonvolatile magnetic media, a magnetic disk drive that reads from or writes to a removable, nonvolatile magnetic disk, and an optical disk drive that reads from or writes to a removable, nonvolatile optical disk such as a CD ROM, DVD, and Blu-Ray® disk, or other optical media. Computer-readable storage media 822 may include, but is not limited to, Zip® drives, flash memory cards, universal serial bus (USB) flash drives, secure digital (SD) cards, DVD disks, digital video tape, and the like. Computer-readable storage media 822 may also include, solid-state drives (SSD) based on non-volatile memory such as flash-memory based SSDs, enterprise flash drives, solid state ROM, and the like, SSDs based on volatile memory such as solid state RAM, dynamic RAM, static RAM, DRAM-based SSDs, magnetoresistive RAM (MRAM) SSDs, and hybrid SSDs that use a combination of DRAM and flash memory based SSDs. The disk drives and their associated computer-readable media may provide non-volatile storage of computer-readable instructions, data structures, program modules, and other data for computer system 800.

Communications subsystem 824 provides an interface to other computer systems and networks. Communications subsystem 824 serves as an interface for receiving data from and transmitting data to other systems from computer system 800. For example, communications subsystem 824 may enable computer system 800 to connect to one or more devices via the Internet. In some embodiments communications subsystem 824 can include radio frequency (RF) transceiver components for accessing wireless voice and/or data networks (e.g., using cellular telephone technology, advanced data network technology, such as 3G, 4G or EDGE (enhanced data rates for global evolution), WiFi (IEEE 802.11 family standards, or other mobile communication technologies, or any combination thereof), global positioning system (GPS) receiver components, and/or other components. In some embodiments communications subsystem 824 can provide wired network connectivity (e.g., Ethernet) in addition to or instead of a wireless interface.

In some embodiments, communications subsystem 824 may also receive input communication in the form of structured and/or unstructured data feeds 826, event streams 828, event updates 830, and the like on behalf of one or more users who may use computer system 800.

By way of example, communications subsystem 824 may be configured to receive data feeds 826 in real-time from users of social networks and/or other communication services such as Twitter® feeds, Facebook® updates, web feeds such as Rich Site Summary (RSS) feeds, and/or real-time updates from one or more third party information sources.

Additionally, communications subsystem 824 may also be configured to receive data in the form of continuous data streams, which may include event streams 828 of real-time events and/or event updates 830, that may be continuous or unbounded in nature with no explicit end. Examples of applications that generate continuous data may include, for example, sensor data applications, financial tickers, network performance measuring tools (e.g. network monitoring and traffic management applications), clickstream analysis tools, automobile traffic monitoring, and the like.

Communications subsystem 824 may also be configured to output the structured and/or unstructured data feeds 826, event streams 828, event updates 830, and the like to one or more databases that may be in communication with one or more streaming data source computers coupled to computer system 800.

Computer system 800 can be one of various types, including a handheld portable device (e.g., an iPhone® cellular phone, an iPad® computing tablet, a PDA), a wearable device (e.g., a Google Glass® head mounted display), a PC, a workstation, a mainframe, a kiosk, a server rack, or any other data processing system.

Due to the ever-changing nature of computers and networks, the description of computer system 800 depicted in the figure is intended only as a specific example. Many other configurations having more or fewer components than the system depicted in the figure are possible. For example, customized hardware might also be used and/or particular elements might be implemented in hardware, firmware, software (including applets), or a combination. Further, connection to other computing devices, such as network input/output devices, may be employed. Based on the disclosure and teachings provided herein, other ways and/or methods to implement the various embodiments should be apparent.

As used herein, the terms “about” or “approximately” or “substantially” may be interpreted as being within a range that would be expected by one having ordinary skill in the art in light of the specification.

In the foregoing description, for the purposes of explanation, numerous specific details were set forth in order to provide a thorough understanding of various embodiments. It will be apparent, however, that some embodiments may be practiced without some of these specific details. In other instances, well-known structures and devices are shown in block diagram form.

The foregoing description provides exemplary embodiments only, and is not intended to limit the scope, applicability, or configuration of the disclosure. Rather, the foregoing description of various embodiments will provide an enabling disclosure for implementing at least one embodiment. It should be understood that various changes may be made in the function and arrangement of elements without departing from the spirit and scope of some embodiments as set forth in the appended claims.

Specific details are given in the foregoing description to provide a thorough understanding of the embodiments. However, it will be understood that the embodiments may be practiced without these specific details. For example, circuits, systems, networks, processes, and other components may have been shown as components in block diagram form in order not to obscure the embodiments in unnecessary detail. In other instances, well-known circuits, processes, algorithms, structures, and techniques may have been shown without unnecessary detail in order to avoid obscuring the embodiments.

Also, it is noted that individual embodiments may have beeen described as a process which is depicted as a flowchart, a flow diagram, a data flow diagram, a structure diagram, or a block diagram. Although a flowchart may have described the operations as a sequential process, many of the operations can be performed in parallel or concurrently. In addition, the order of the operations may be re-arranged. A process is terminated when its operations are completed, but could have additional steps not included in a figure. A process may correspond to a method, a function, a procedure, a subroutine, a subprogram, etc. When a process corresponds to a function, its termination can correspond to a return of the function to the calling function or the main function.

The term “computer-readable medium” includes, but is not limited to portable or fixed storage devices, optical storage devices, wireless channels and various other mediums capable of storing, containing, or carrying instruction(s) and/or data. A code segment or machine-executable instructions may represent a procedure, a function, a subprogram, a program, a routine, a subroutine, a module, a software package, a class, or any combination of instructions, data structures, or program statements. A code segment may be coupled to another code segment or a hardware circuit by passing and/or receiving information, data, arguments, parameters, or memory contents. Information, arguments, parameters, data, etc., may be passed, forwarded, or transmitted via any suitable means including memory sharing, message passing, token passing, network transmission, etc.

Furthermore, embodiments may be implemented by hardware, software, firmware, middleware, microcode, hardware description languages, or any combination thereof. When implemented in software, firmware, middleware or microcode, the program code or code segments to perform the necessary tasks may be stored in a machine readable medium. A processor(s) may perform the necessary tasks.

In the foregoing specification, features are described with reference to specific embodiments thereof, but it should be recognized that not all embodiments are limited thereto. Various features and aspects of some embodiments may be used individually or jointly. Further, embodiments can be utilized in any number of environments and applications beyond those described herein without departing from the broader spirit and scope of the specification. The specification and drawings are, accordingly, to be regarded as illustrative rather than restrictive.

Additionally, for the purposes of illustration, methods were described in a particular order. It should be appreciated that in alternate embodiments, the methods may be performed in a different order than that described. It should also be appreciated that the methods described above may be performed by hardware components or may be embodied in sequences of machine-executable instructions, which may be used to cause a machine, such as a general-purpose or special-purpose processor or logic circuits programmed with the instructions to perform the methods. These machine-executable instructions may be stored on one or more machine readable mediums, such as CD-ROMs or other type of optical disks, floppy diskettes, ROMs, RAMs, EPROMs, EEPROMs, magnetic or optical cards, flash memory, or other types of machine-readable mediums suitable for storing electronic instructions. Alternatively, the methods may be performed by a combination of hardware and software.

What is claimed is:

1. A method of training models to characterize film thicknesses on semiconductor substrates, the method comprising:
receiving a film thickness profile representing a film on a semiconductor substrate design;
simulating a light source being reflected off of the film on the semiconductor substrate and being captured by a camera;
converting spectral data captured by the camera into one or more images for a wafer having the film thickness profile; and
labeling the one or more images with the film thickness profile for training a machine-learning model.

2. The method of claim 1, wherein the film thickness profile comprises measurements of a thickness of the film extending from a center of the semiconductor substrate to a periphery of the semiconductor substrate.

3. The method of claim 1, wherein the film thickness profile comprises thicknesses of the film at a plurality of different radii extending out from a center of the semiconductor substrate.

4. The method of claim 1, wherein the film thickness profile is specific to a film material and one or more underlying film materials.

5. The method of claim 1, wherein the semiconductor substrate design comprises a design file including a film material.

6. The method of claim 1, wherein simulating the light source being reflected off of the film on the semiconductor substrate and being captured by the camera comprises:
receiving a light spectra for a light source, wherein the light source comprises a laser that will be directed to a physical semiconductor substrate during a semiconductor process.

7. The method of claim 6, wherein simulating the light source being reflected off of the film on the semiconductor substrate and being captured by the camera further comprises:
calculating a reflected spectra from the film that will be captured by a physical camera using thin-film inference formulas, physical properties of the film, a film thickness at a location based on the film thickness profile, and underlying film properties.

8. The method of claim 1, wherein the semiconductor substrate design does not require a physical substrate to be manufactured or processed in order to simulate the light source being reflected off of the film and converting the spectral data into the image of the wafer.

9. A system comprising:
one or more processors; and
one or more memory devices comprising instructions that, when executed by the one or more processors, cause the one or more processors to perform operations comprising:
receiving a film thickness profile representing a film on a semiconductor substrate design;
simulating a light source being reflected off of the film on the semiconductor substrate and being captured by a camera;
converting spectral data captured by the camera into one or more images for a wafer having the film thickness profile; and
labeling the one or more images with the film thickness profile for training a machine-learning model.

10. The system of claim 9, wherein converting the spectral data captured by the camera into the one or more images of a wafer having the film thickness profile comprises:
translating the spectral data captured by the camera into RGB pixel values.

11. The system of claim 10, wherein translating the spectral data captured by the camera into the RGB pixel values comprises:
using a lookup table that stores RGB pixel values that correspond to received spectral wavelengths for the camera.

12. The system of claim 9, wherein labeling the one or more images with the film thickness profile comprises:
associating the image with a thickness measurement at a specific location on the semiconductor substrate design to generate a training pair for the machine learning model.

13. The system of claim 9, wherein simulating the light source being reflected off of the film comprises:
accessing a film material and physical properties of the film material, wherein the machine-learning model is trained specifically for the film material.

14. The system of claim 9, wherein a plurality of simulated images are generated from the film thickness profile, wherein each of the plurality of simulated images corresponds to a thickness value in the film thickness profile.

15. The system of claim 9, wherein a plurality of different film thickness profiles are simulated to generate a training data set for various film thicknesses for a specific film material.

16. One or more non-transitory computer-readable media comprising instructions that, when executed by one or more processors, cause the one or more processors to perform operations comprising:
receiving a film thickness profile representing a film on a semiconductor substrate design;
simulating a light source being reflected off of the film on the semiconductor substrate and being captured by a camera;
converting spectral data captured by the camera into one or more images for a wafer having the film thickness profile; and
labeling the one or more images with the film thickness profile for training a machine-learning model.

17. The one or more non-transitory computer-readable media of claim 16, wherein the one or images comprise monochrome.

18. The one or more non-transitory computer-readable media of claim 16, wherein the film thickness profile includes a simulated wafer defect, wherein the machine-learning model is trained to recognize a wafer defect corresponding to the simulated wafer defect.

19. The one or more non-transitory computer-readable media of claim 16, wherein the operations further comprise adding simulated signal noise when simulating the light source being reflected off the film on the semiconductor substrate and being captured by the camera.

20. The one or more non-transitory computer-readable media of claim 16, wherein labeling the one or more images with the film thickness profile comprises:
labeling the one or more images with ranges of film thicknesses.
